(19) United States
(12) Patent Application Publication
(10) Pub. No.: US 2014/0186651 A1
(43) Pub. Date: Jul. 3, 2014

(54) PRINTED CIRCUIT BOARD HAVING COPPER PLATED LAYER WITH ROUGHNESS AND METHOD OF MANUFACTURING THE SAME

(71) Applicant: SAMSUNG ELECTRO-MECHANICS CO., LTD., Suwon-si (KR)

(72) Inventors: Sung Han, Suwon-si (KR); Yoon Su Kim, Suwon-si (KR); Doo Sung Jung, Suwon-si (KR); Eun Jung Lim, Suwon-si (KR); Kyoung Moo Harr, Suwon-si (KR); Kyung Suk Shim, Suwon-si (KR); Kyung Seob Oh, Suwon-si (KR)

(73) Assignee: SAMSUNG ELECTRO-MECHANICS CO., LTD., Suwon-si (KR)

(21) Appl. No.: 14/140,392

(22) Filed: Dec. 24, 2013

(30) Foreign Application Priority Data
Dec. 28, 2012 (KR) 10-2012-0157130

(51) Int. Cl. H05K 1/09; H05K 3/00

(52) U.S. Cl. CPC H05K 1/09; H05K 3/002
USPC 428/612; 428/637; 430/318

(57) ABSTRACT

Disclosed herein are a printed circuit board having a copper plated layer with an anchor shaped surface and roughness by forming the copper plated layer having an anisotropic crystalline orientation structure using a plating inhibitor at the time of forming the copper plated layer serving as a circuit wiring and using composite gas plasma and a dilute acid solution, and a method of manufacturing the same.

### CROSS REFERENCE TO RELATED APPLICATION

This application claims the benefit of Korean Patent Application No. 10-2012-0157130, filed on Dec. 28, 2012, entitled “Printed Circuit Board Having Copper Plated Layer with Roughness and Method of Manufacturing the Same”, which is hereby incorporated by reference in its entirety into this application.

### BACKGROUND OF THE INVENTION

1. Technical Field

The present invention relates to a printed circuit board having a copper plated layer with roughness and a method of manufacturing the same.

2. Description of the Related Art

Recently, as electronic devices have been advanced and complicated functions have been required, a printed circuit board has gradually been light, thin, and miniaturized. In order to satisfy these demands, a wiring of a printed circuit has become more complicated, highly-densified, and highly-functionalized.

As described above, as the electronic device is miniaturized and has an improved performance, a multi-layer printed circuit board should be highly-densified, miniaturized, and thinned, and have high performance. Particularly, in the multi-layer printed circuit board, fineness and high density of the wiring has been mainly developed. Therefore, in an insulating layer of the multi-layer printed circuit board, thermal, mechanical, and electrical properties has become important. Particularly, in order to minimize warpage generated while electronic and electrical devices are subjected to a reflow process in a mounting process thereof, low coefficient of thermal expansion (CTE), high glass transition temperature (Tg), and high modulus properties are demanded.

Currently, as a measure for decreasing a line width and space of a copper wiring, photo-resist for wafer level package (hereinafter, referred to as an “insulating PR”) has significantly become prominent in a semiconductor industry and a printed circuit board industry. Particularly, since a blind via hole (BVH) may be easily implemented in the package, this insulating PR has been prominent. However, adhesive force of the insulating PR on a copper redistribution layer (RDL) is not uniform. Particularly, at the time of laminating multi-layers, a defect case in which the adhesive force is decreased due to repetitive thermal impact caused by a high drying temperature of the insulating PR at the time of multi-layering has been frequently observed. Therefore, there is a need to perform surface-processing or surface-treating on the copper RDL.

As a method for increasing the adhesive force, a method of controlling a surface roughness to generate an interlocking phenomenon, that is, an anchoring phenomenon may be significantly effective. In addition, in the case of using an adhesion promoter, since uniform adhesive force may be reproducibly implemented using a slight surface roughness, an effective surface processing technique for a fine circuit is necessarily demanded.

In view of implementing the fine circuit, for example, in the case in which a line width and space is 5 μm, respectively, since an average surface roughness Ra is about 0.3 μm and the maximum value is 1 μm or more, in order to implement the wiring so that the line width and space is 5 μm, respectively, significantly difficult correction should be performed, and in a fine line width of 5 μm or less, the wiring may not be substantially implemented.

Further, when a surface of the flat copper layer is a rough surface having a Ra of 0.3 μm or more, since large transmission loss may be generated in transmitting a signal at a high frequency, in the copper layer of 10 μm or less thickness, it should be possible to control an arithmetic average roughness to about 0.01 μm. Meanwhile, since a measure of increasing the surface roughness to increase adhesive force and a measure of implementing a flat surface for circuit implementation and preventing signal loss are conflicting, a method of finding a balance between surface roughness, circuit implementation, and minimizing signal loss has been demanded. As shown in Patent Document 1, according to the related art, in order to implement surface roughness on a surface of a copper RDL, physical processing, that is, surface processing such as sand blasting, sand paper, and rough powder slurry milling, has been performed thereon. However, in this surface processing method, the surface may become excessively rough, uniform and reproducible fine-control may be difficult, and a pattern itself may be deformed and damaged in a pattern of 10 μm or less.

In addition, as an existing chemical method, a method of oxidizing a copper pattern by a wet process or etching the copper pattern using an acidic or alkaline solution to obtain a rough surface has been mainly used. When chemical impact is applied on copper in the fine pattern by the method as describe above, dimension of the circuit may be changed. Particularly, a strong acid or alkaline solution may generate a severe cut-off phenomenon during a seed etching of the fine pattern or an electroplated copper RDL, and it is not easy to reproduce and control the process.

Therefore, in order to surface-process the RDL pattern of the fine circuit for increasing the adhesive force, a reproducible chemical method of increasing roughness that does not cause large damage has been required.

(Patent Document 1) U.S. Pat. Registration No. 5,622,782

### SUMMARY OF THE INVENTION

In the present invention, it was confirmed that excellent adhesive force between a copper plated layer and an insulating film was obtained by forming a copper plated layer having an anchor structure in a surface thereof using crystalline orientation structural features of copper determined by adjusting a concentration of a plating inhibitor at the time of forming a copper plated layer and a plasma etching method using composite gas, and the present invention was completed based on this fact.

The present invention has been made in an effort to provide a printed circuit board including a copper plating layer having excellent adhesive force.

Further, the present invention has been made in an effort to provide a simple and economic method of manufacturing a printed circuit board including a copper plating layer having excellent adhesive force.

Furthermore, the present invention has been made in an effort to provide a simple and economic method of manufacturing a printed circuit board including a copper plating layer having excellent adhesive force and low signal transmission loss.

According to a preferred embodiment of the present invention, there is provided a printed circuit board (hereinafter, referred to as a ‘first invention’) including: a board; a copper foil layer formed on the board; and a copper plated layer formed on the copper foil layer and having an anisotropic crystalline orientation structure.

In the first invention, the anisotropic crystalline orientation structure may be configured of 111 and 220 type crystalline orientation structures.

In the first invention, the copper plated layer may have an arithmetic average roughness Ra of 0.01 to 0.5 μm.

In the first invention, the copper plated layer may have the maximum average roughness Rz of 0.01 to 5 μm.

In the first invention, an upper surface of the copper plated layer or upper and side surfaces thereof may be provided with roughness.

According to another preferred embodiment of the present invention, there is provided a printed circuit board (hereinafter, referred to as a ‘second invention’) including: a board; copper foil layer formed on the board; and a copper plated layer formed on the copper foil layer and having an anchor structure in a surface thereof.

In the second invention, an insulating layer may be positioned on the surface having the anchor structure.

According to another preferred embodiment of the present invention, there is provided a method of manufacturing a printed circuit board having a copper plated layer with roughness, the method (hereinafter, referred to as a ‘third invention’) including: applying photoresist on a board including a copper foil layer and then forming a pattern part on which the copper foil layer is exposed; performing copper plating on the exposed pattern part so that an anisotropic crystalline orientation structure is formed; removing the photoresist to form a copper plated layer; plasma- treating a surface of the copper plated layer to form a copper halide corrosion layer; and removing the copper halide corrosion layer using an acid solution.

According to another preferred embodiment of the present invention, there is provided a method of manufacturing a printed circuit board having a copper plated layer with roughness, the method (hereinafter, referred to as a ‘fourth invention’) including: applying photoresist on a board including a copper foil layer and then forming a pattern part on which the copper foil layer is exposed; performing copper plating on the exposed pattern part so that an anisotropic crystalline orientation structure is formed; plasma-treating a surface of the copper plated layer to form a copper halide corrosion layer; removing the copper halide corrosion layer using an acid solution; and removing the photoresist to form a copper plated layer on the board.

In the third or fourth invention, the anisotropic crystalline orientation structure may be configured of 111 and 220 type crystalline orientation structures.

In the third or fourth invention, the performing of the copper plating may be performed using a plating solution containing polyethylene glycol, and a ratio of 111 type and 220 type crystalline orientation structures may be adjusted by an amount of polyethylene glycol.

In the third or fourth invention, the plasma may be selected from a group consisting of direct current (DC) grow discharge plasma, capacitively coupled plasma (CCP), inductively coupled plasma (ICP), electron cyclone resonance (ECR) plasma, and helicon/helical structure plasma and generate pressure of 10⁻⁴ to 10 Torr.

In the third or fourth invention, the gas used for forming the plasma may be composite gas containing 10 to 90 vol. % of halogen gas.

In the third or fourth invention, the halogen gas may be chlorine-included gas.

In the third or fourth invention, the acid solution may be at least one selected from a group consisting of hydrochloric acid, acetic acid, sulfuric acid, nitric acid, and phosphoric acid.

In the third or fourth invention, the roughness may form an anchor.

In the third or fourth invention, the copper plated layer may have an arithmetic average roughness Ra of 0.01 to 0.5 μm.

In the third or fourth invention, the copper plated layer may have the maximum average roughness Rz of 0.01 to 5 μm.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional diagram of a general printed circuit board capable of using a copper plated layer according to a preferred embodiment of the present invention;

FIG. 2 is a block diagram showing a process of plasma-treating and etching on the copper plated layer provided in the printed circuit board according to the preferred embodiment of the present invention;

FIG. 3 is a block process diagram showing a method of manufacturing a printed circuit board according to the preferred embodiment of the present invention;

FIG. 4 is a schematic diagram showing a specific example of the method of manufacturing a printed circuit board according to the preferred embodiment of the present invention; and

FIG. 5 is a schematic diagram showing another specific example of the method of manufacturing a printed circuit board according to the preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

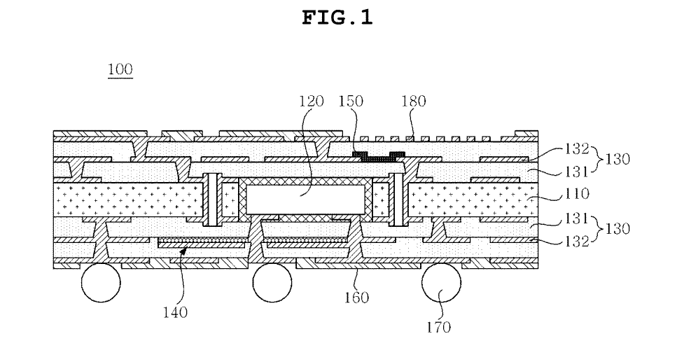

FIG. 1 is a cross-sectional view of a general printed circuit board capable of using a copper plated layer according to a first preferred embodiment of the present invention. Referring to FIG. 1, a printed circuit board 100 may be an embedded board on which electronic components are embedded. More specifically, the printed circuit board 100 may include an insulator or a prepreg 110 provided with a cavity, an electronic component 120 disposed in the cavity, and a buildup layer 130 disposed on at least one of upper and lower surfaces of the insulator or the prepreg 110 including the electronic component 120. The buildup layer 130 may include an insulating layer 131 disposed on at least one of the upper and lower surfaces of the insulator 110 and a circuit layer 132 disposed on the insulating layer 131 and connecting between the layers.

Here, the electronic component 120 may be, for example, an active device such as a semiconductor device. In addition, the printed circuit board 100 may not include only one electronic component 120 embedded thereon but further include at least one additional electronic component, for example, a capacitor 140, a resistance device 150, and the like. In the preferred embodiment of the present invention, a kind or the number of electronic component is not limited thereto. Here, the insulator or the prepreg 110 and the insulating layer 131 may serve to insulate the circuit layers from each other or to insulate the electronic components from each other and simultaneously serve as a structural material for maintaining rigidity of a package.

In this case, when a wiring density of the printed circuit board 100 is increased, the insulator or the prepreg 110 and the insulating layer 131 need to have a low permittivity property in order to simultaneously decrease noise between the circuit layers and parasitic capacitance, and have a low dielectric loss property in order to improve an insulation property.

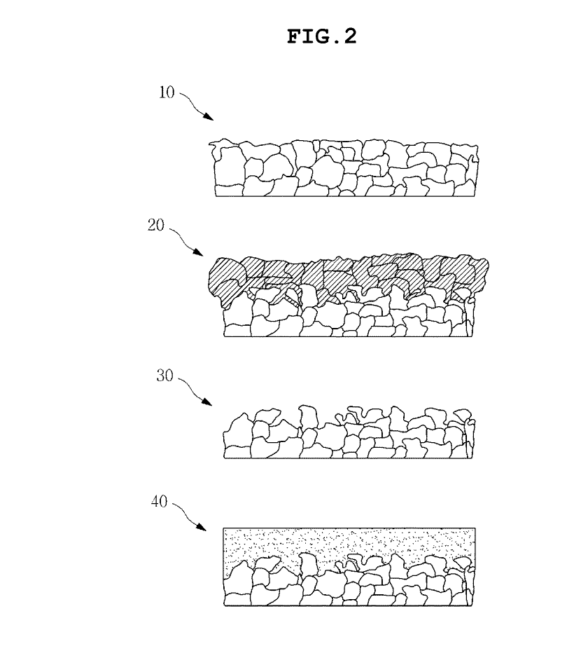

In the present invention, in the case of performing copper-plating for forming a circuit pattern, a specific anisotropic crystalline orientation structure obtained by adjusting a concentration of a plating inhibitor may be used. FIG. 2 is a diagram showing a copper plated layer having the specific anisotropic crystalline orientation structure as described above.

Generally, the plating inhibitor is used in order to adjust a degree of plating at the time of copper plating. For example, polyethylene glycol (PEG) is used as the plating inhibitor. The copper plated layer formed by an electro plating or electroless plating method has a specific crystalline orientation structure, and generally, this crystalline orientation structure is referred to as 111, 200, and 220. A 111 type indicates a structure in which orientation of crystals is most densely arranged, and a 220 type indicates a structure in which orientation of crystals is most sparsely arranged. A 200 type is an intermediate type and indicates a structure in which orientation of crystals is relatively densely arranged.

As shown in FIG. 2, at the time of forming the copper plated layer, these three types of the crystalline orientation structures are mixed, and a ratio of these 111, 200, and 220 types may be controlled by adjusting a concentration of polyethylene glycol, which is the plating inhibitor. As a result, a crystal form indicating this orientation difference indicates a difference at the outermost surface of the copper plated layer. In the case of etching this copper plated layer, a copper portion having a 220 type crystal form, which is the most sparse structure, may be firstly etched.

In the present invention, a roughness is formed on a surface of the etched copper plated layer. This roughness has an arithmetic average roughness Ra of 0.02 to 0.5 μm, and the maximum average roughness Rz of 0.2 to 5 μm. In the case in which the arithmetic average roughness is less than 0.02, adhesive force may be decreased, and in the case in which the arithmetic average roughness is more than 0.5, a signal transmission loss rate may be excessively increased. The maximum average roughness causes the same problems as described above.

In addition, an upper surface and a side surface of the copper plated layer may be provided with the roughness, or only the upper surface may be provided with the roughness by changing a manufacturing process of the printed circuit board as described below.

The rough surface formed as described above may form a hook shaped anchor due to a copper crystalline orientation property adjusted at the time of plating. Therefore, structural features, which are entirely different from those of a vertical structure or a tapered three-dimensional structure formed when roughness is formed by etching, are shown. That is, a shape in which a lower portion of a lower end portion of the surface with the roughness is further depressed inwardly is shown, which is generated due to a property of copper orientation formed at the time of plating as described above.

When an insulating resin layer, or the like, is applied after forming the copper plated layer, strong adhesive force between the copper plated layer and the insulating resin layer is required. The surface having anchor structure as described above may have more excellent adhesive force than that of a surface with roughness simply formed by etching. That is, generally, a method of improving the adhesive force by roughness uses an action of increasing a surface area, but in the case in which roughness is formed by copper etching using the property of the anisotropic copper crystalline orientation structure as in the present invention, a copper portion having the 220 type sparse structure as described above may be easily etched, such that the hook shaped anchor structure may be formed by a shape of a copper portion having the 111 type structure. Due to this anchor structure, the surface area may be increased and the insulating resin layer and the copper plated layer have the interlocking structure in which they interlock with each other, such that adhesive force therebetween may be maximized.

Hereinafter, a method of manufacturing a printed circuit board including the copper plated layer as described above will be described in detail. Generally, in order to form the copper plated layer serving as a circuit wiring in the printed circuit board, firstly, a copper foil is laminated on an insulating board, an insulating photo-resist (PR) is applied thereon using the copper layer as a carrier, performing exposure and development processes using a mask provided with a circuit pattern, and then a PR provided with a pattern part is formed. A copper plating for forming the desired circuit pattern is performed on the pattern part formed as described above by the electro plating or electroless plating method.

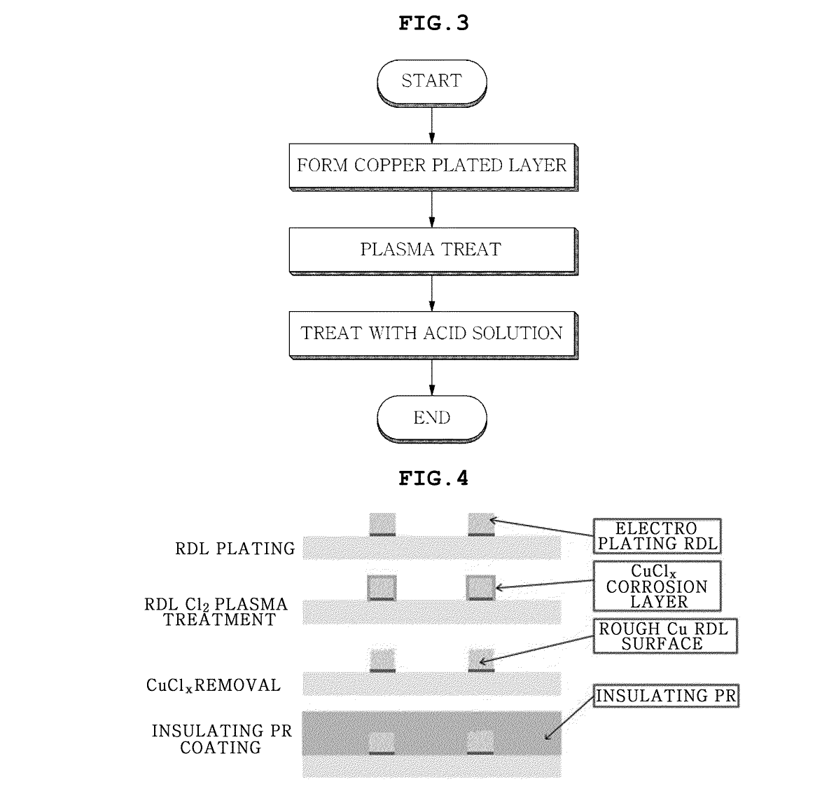

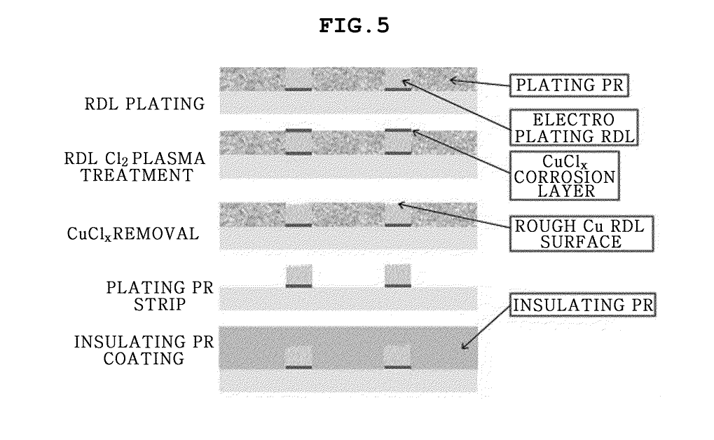

FIG. 3 is a block process diagram showing a method of manufacturing a printed circuit board according to the present invention, and FIGS. 4 and 5 are schematic diagrams showing a method of manufacturing a printed circuit board according to the present invention. A specific example of the present invention will be described with reference to FIGS. 3 and 4. Firstly, a copper foil layer serving as a plating seed layer is formed on an insulating layer, an insulating resin (an insulating PR, or the like) is applied thereto, and then a PR layer provided with a pattern part is formed using a patterned mask. A plated layer serving as a circuit wiring is formed on the pattern part of the PR layer formed as described above by the electro plating method or electroless plating method. In this case, during a process of performing copper-plating, the copper plated layer in which 111, 200, and 220 type crystalline orientation are mixed as described above may be obtained by adjusting an amount of polyethylene glycol, which is the plating inhibitor.

The copper plated layer obtained as described above is disposed in a vacuum chamber and halogen gas is discharged in the vacuum state, such that a halogenated copper (copper halide) corrosion layer is formed on the outermost surface of the copper plated layer. This copper halide corrosion layer is formed of a halogen-metal complex formed by chemical reaction between the halogen gas and copper particles. Here, the halogen gas means gas formed by a halogen atom, wherein the halogen atom corresponds to the group 7 elements in the Periodic Table of Elements, and fluorine (F), chlorine (Cl), bromine (Br), and iodine (I), and the like correspond thereto. FIG. 2 is shows a copper halide corrosion layer 20 formed as described above and shows that the surface of the copper plated layer forms a halogen-metal complex while being expanded at the time of reaction with the halogen gas.

The copper halide corrosion layer formed as described above is firstly formed in the copper portion having the 220 type crystal structure, which is the sparse crystal structure. Therefore, copper having the 220 type crystal structure at an outer portion of the copper plated layer reacts with the halogen gas, such that the copper halide corrosion layer is formed at this portion. Therefore, preferred etching using an acid solution to be described below may be performed.

On the other hand, relatively weak chemical reaction is carried out between the halogen gas and copper having 111 type crystal structure, that is, the dense crystal structure, such that the copper halide corrosion layer is weakly formed. Therefore, at the time of etching using an acid solution to be described below, the copper portion having the 111 type crystal structure at the outer portion of the copper plated layer remains as it is.

The halogen gas is accurately composite gas in which halogen gas, argon gas, and hydrogen gas are mixed with each other, wherein the halogen gas serves to chemically react with copper to form the copper halide corrosion layer, and the argon (Ar) gas serves to promote the etching. Therefore, another gas capable of promoting the etching may be used in the present invention. In addition, the hydrogen gas serves to stabilize the etching.

In the composite gas, a content of the halogen gas, which is the main gas, is 10 to 90 vol. %, a content of the argon gas is 0 to 90 vol. %, and a content of the hydrogen gas is 0 to 30 vol. %, based on the total volume. This composite gas forms a plasma state under an environment in which pressure is decreased (about 10⁻⁴ to 10 Torr) in the vacuum chamber. As an example of this plasma includes direct current (DC) glow discharge plasma, capacitively coupled plasma (CCP), inductively coupled plasma (ICP), electron cyclone resonance (ECR) plasma, helicon/helical structure plasma, and the like.

As described above, the copper halide corrosion layer is formed using the composite gas plasma, and then the copper halide corrosion layer is removed using the acid solution. The acid solution used in this process may be at least one selected from a group consisting of hydrochloric acid, acetic acid, sulfuric acid, nitric acid, and phosphoric acid, but is not limited thereto. Meanwhile, as the acid solution, a dilute acid solution having a concentration of 5% or less may be used. When the concentration of the acid solution is increased, the copper plated layer may be excessively etched, thereby generating circuit damage.

When the etching as described above is completed, a copper plated layer having the surface with roughness may be obtained as shown in FIG. 2. As shown in FIG. 2, copper crystal having the 111 type structure remains on a surface of a copper plated layer 30, and most of the copper crystals having the 220 type structure at the outer portion are removed. Describing the surface of the copper plated layer 30, it may be appreciated that the hook shaped anchor structure is formed unlike the case in which roughness is formed by simple etching. Due to this anchor shape, the copper plated layer and an insulating PR layer may interlock with each other to impart strong adhesive force.

Unlike the general method of forming a rough surface of a copper plated layer to increase adhesive force, in the case in which a composite gas plasma etching method using a difference in copper crystal orientation at the time of plating as the present invention, the outermost surface area may be increased, and the copper plated layer and the insulating PR layer physically may interlock with each other, such that strong adhesive force may be obtained.

FIG. 2 shows that after an insulating resin layer 40 is applied, the copper plated layer 30 and the insulating resin layer 40 interlock with each other to have a structure in which the adhesive force is improved.

Another specific example of the present invention will be described below.

FIG. 5 is a schematic diagram for describing this specific example. Referring to FIG. 5, after a photoresist provided with a pattern part is applied, copper plating is performed on the pattern part so as to have an anisotropic crystalline orientation structure as the above-mentioned method, and then plasma treatment is performed thereon using composite gas in a vacuum chamber by the above-mentioned method in a state in which the photoresist is not removed. In this case, unlike the above-mention specific example (the case in FIG. 4), a copper halide corrosion layer is formed only on an upper surface of a copper plated layer. This copper corrosion layer is removed using a dilute acid solution and the insulating photoresist layer is removed, such that a copper plated layer of which only an upper portion has roughness may be obtained. As described above, when only the upper portion has roughness, adhesive force may be decreased, as compared with the case in which the side surface also has roughness, but the signal transmission loss rate of the copper plated layer serving the circuit wiring may be decreased. That is, as described above, a measure of increasing the surface roughness to increase adhesive force and a measure of implementing a flat surface for circuit implementation and preventing signal loss are conflicting. However, when the rough surface having the hook shaped anchor structure is formed only the upper portion as described above, the adhesive force may be increased due to the anchor phenomenon, and the signal transmission loss rate may be decreased at the same time since the roughness may be minimized.

Hereinafter, the present invention will be described with reference to Inventive Examples, but the present invention is not limited thereto.

### INVENTIVE EXAMPLE 1

A board in which a copper film is grown to have a thickness of 8 μm by an electroplating method in an electro plating bath from a copper foil seed layer having an area wider than that of a copper RDL such as copper dummy patterns, ground pattern, and PDN wiring pattern was prepared. Then, a plating photoresist was removed, wet surface cleaning (using acid and water) was performed on the board, and then the board was sufficiently dried at 120° C. for 30 minutes using nitrogen gas or in a vacuum oven. The sufficiently dried board was charged in a vacuum chamber, and basic vacuum was exhausted to 5×10⁻⁷ Torr before working. Next, argon gas is purged, and Cl₂ gas and argon or hydrogen gas is supplied into the vacuum chamber to discharge plasma, and then radio frequency (RF) bias is applied to the board. Here, in a system in which gas was configured of Cl₂ gas and argon gas, a ratio of argon was adjusted so as not to exceed about 40 vol. %, and in a system in which the gas was configured of Cl₂ gas, hydrogen gas, and argon gas, a ratio of hydrogen was adjusted so as not to exceed about 5 vol. %. The ratio of the argon gas was adjusted to 40 vol. %. The chlorine gas was adjusted to 50 vol. %. A copper surface irradiated with the argon and chlorine gas was formed with a copper halide corrosion layer (CuCl₂) in a 220 type direction. This halide based compound was removed with diluted hydrochloric acid, and the copper surface treated as described above had an anchor shape and an average roughness of about 0.05 μm. Then, an insulating layer coated with an insulating photoresist so as to improve adhesive force was implemented on the copper surface.

### INVENTIVE EXAMPLE 2

In an electro plating bath, after a plating process of a copper RDL was performed at an average thickness of 8 μm, wet surface cleaning (using acid and water) was performed on the board in a state in which a plating photoresist was not removed, and then the board was sufficiently dried at 120° C. for about 30 minutes using nitrogen gas or in a vacuum oven. The sufficiently dried board was charged in a vacuum chamber, and basic vacuum was exhausted to 5×10⁻⁷ Torr before working. Next, argon is purged, and Cl₂ and argon or hydrogen gas is supplied into the vacuum chamber to discharge plasma, and then radio frequency (RF) bias is applied to the board. Here, in a system in which gas was configured of Cl₂ gas and argon gas, a ratio of argon was adjusted so as not to exceed about 40 vol. %, and in a system in which the gas was configured of Cl₂ gas, hydrogen gas, and argon gas, a ratio of hydrogen was adjusted so as not to exceed about 5 vol. %. The ratio of argon gas was adjusted to 40 vol. %. The chlorine gas was adjusted to 50 vol. %. A copper surface irradiated with the argon and chlorine gas was formed with a copper halide corrosion layer (CuCl₂) in a 220 type direction, wherein the copper halide corrosion layer was formed on only an upper portion. This halide based compound was removed with diluted hydrochloric acid, and then, the plating photoresist was removed. The copper surface treated as described above had an anchor shape and an average roughness of about 0.05 μm. Then, an insulating layer coated with an insulating photoresist so as to improve adhesive force was implemented on the copper surface.

Evaluation of Peel Strength Property of Copper Foil

After copper foil having a width of 1 cm was peeled off from a surface of the copper clad laminate, the peel strength of the copper foil was measured using a universe testing machine (UTM, KTW 100). The obtained results were shown in the following Table 1 (90 degree peel off test, crosshead rate: 50 mm/min).

TABLE 1

| | | Interfacial Adhesion |
|---|---|---|
| | Condition | Strength (kgf/cm) |
| Inventive Example 1 | Upper and side corrosion | 0.5 |
| | layers formation | |
| Inventive Example 2 | Upper corrosion layer | 0.3 |
| | formation | |
| Comparative Example | General etching | 0.1 |

In the Comparative Example, adhesion strength between a copper plated layer and an insulating resin layer was measured in the case in which the copper plating was performed by the general method without adjusting copper crystal orientation. In this case, the sample plating forming conditions were applied as those in inventive Example 1 except that the copper crystal orientation was not adjusted.

As shown in Table 1, it may be appreciated that in the case in which the copper crystalline orientation was adjusted by adjusting a concentration of polyethylene glycol according to Inventive Example 1, interfacial adhesion strength between the copper wiring layer and insulating resin layer was 0.5 kgf/cm, and in the case in which etching using the copper crystalline orientation was performed on only the upper portion according to Inventive Example 2, relatively good interfacial adhesion strength of 0.3 kgf/cm was obtained.

In the printed circuit board according to the present invention, the copper plated layer with roughness is formed on the surface, such that the adhesive force with the copper plated layer and the insulating resin layer applied thereon may be excellent. In addition, the surface having the roughness is limited, such that the printed circuit board having low signal transmission loss may be provided.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A printed circuit board comprising:
a board;
a copper foil layer formed on the board; and
a copper plated layer formed on the copper foil layer and having an anisotropic crystalline orientation structure.

2. The printed circuit board as set forth in claim 1, wherein the anisotropic crystalline orientation structure is configured of 111 and 220 type crystalline orientation structures.

3. The printed circuit board as set forth in claim 1, wherein the copper plated layer has an arithmetic average roughness Ra of 0.01 to 0.5 μm.

4. The printed circuit board as set forth in claim 1, wherein the copper plated layer has the maximum average roughness Rz of 0.01 to 5 μm.

5. The printed circuit board as set forth in claim 1, wherein an upper surface of the copper plated layer or upper and side surfaces thereof are provided with roughness.

6. A printed circuit board comprising:
a board;
a copper foil layer formed on the board; and
a copper plated layer formed on the copper foil layer and having an anchor structure on a surface thereof.

7. The printed circuit board as set forth in claim 6, wherein an insulating layer is positioned on the surface having the anchor structure.

8. A method of manufacturing a printed circuit board having a copper plated layer with roughness, the method comprising:
applying photoresist on a board including a copper foil layer and then forming a pattern part on which the copper foil layer is exposed;
performing copper plating on the exposed pattern part so that an anisotropic crystalline orientation structure is formed;
removing the photoresist to form a copper plated layer;
plasma-treating a surface of the copper plated layer to form a copper halide corrosion layer; and
removing the copper halide corrosion layer using an acid solution.

9. A method of manufacturing a printed circuit board having a copper plated layer with roughness, the method comprising:
applying photoresist on a board including a copper foil layer and then forming a pattern part on which the copper foil layer is exposed;
performing copper plating on the exposed pattern part so that an anisotropic crystalline orientation structure is formed;
plasma-treating a surface of the copper plated layer to form a copper halide corrosion layer;
removing the copper halide corrosion layer using an acid solution; and
removing the photoresist to form a copper plated layer on the board.

10. The method as set forth in claim 8, wherein the anisotropic crystalline orientation structure is configured of 111 and 220 type crystalline orientation structures.

11. The method as set forth in claim 8, wherein the performing of the copper plating is performed using a plating solution containing polyethylene glycol, and a ratio of 111 type and 220 type crystalline orientation structures is adjusted by an amount of polyethylene glycol.

12. The method as set forth in claim 8, wherein the plasma is selected from a group consisting of direct current (DC) glow discharge plasma, capacitively coupled plasma (CCP), inductively coupled plasma (ICP), electron cyclone resonance (ECR) plasma, and helicon/helical structure plasma and generates pressure of 10⁻⁴ to 10 Torr.

13. The method as set forth in claim 8, wherein gas used for forming the plasma is composite gas containing 10 to 90 vol. % of halogen gas.

14. The method as set forth in claim 13, wherein the halogen gas is chlorine-included gas.

15. The method as set forth in claim 8, wherein the acid solution is at least one selected from a group consisting of hydrochloric acid, acetic acid, sulfuric acid, nitric acid, and phosphoric acid.

16. The method as set forth in claim 8, wherein the roughness forms an anchor.

17. The method as set forth in claim 8, wherein the copper plated layer has an arithmetic average roughness Ra of 0.01 to 0.5 μm.

18. The method as set forth in claim 8, wherein the copper plated layer has the maximum average roughness Rz of 0.01 to 5 μm.
